(19) United States
(12) Patent Application Publication
(10) Pub. No.: US 2026/0043884 A1
(43) Pub. Date: Feb. 12, 2026

(54) High Accuracy Detector For Non-Sinusoidal Generator

(71) Applicant: MKS Inc., Andover, MA (US)

(72) Inventors: Zachary SORRELL, Rochester, NY (US); Aaron RADOMSKI, Conesus, NY (US)

(21) Appl. No.: 18/795,887

(22) Filed: Aug. 6, 2024

(51) Int. Cl. G01R 35/00; G01R 23/16

(52) U.S. Cl. CPC G01R 35/005; G01R 23/16

(57) ABSTRACT

A power supply system includes a RF generator configured to output a nonsinusoidal signal to a load, at least one wideband sensor configured to measure at least one of a voltage and a current of the nonsinusoidal signal, and a controller coupled to the RF generator. The controller is configured to receive a waveform associated with the nonsinusoidal signal from the at least one wideband sensor, determine an uncalibrated value at each of a number of harmonic components of the waveform, and generate a calibrated value at each of the number of harmonic components based on the corresponding uncalibrated value and a frequency response of the at least one wideband sensor. Other example power supplies, computer-readable mediums, and controllers for RF generators are also disclosed.

### FIELD

The present disclosure relates to RF generator systems and to control of RF generators.

### BACKGROUND

Plasma processing is frequently used in semiconductor fabrication. In plasma processing, ions are accelerated by an electric field to etch material from or deposit material onto a surface of a substrate. In one basic implementation, the electric field is generated based on Radio Frequency (RF) or Direct Current (DC) power signals generated by a respective RF or DC generator of a power delivery system. The power signals generated by the generator must be precisely controlled to effectively execute plasma etching.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

According to one aspect of the present disclosure, a power supply system includes a RF generator configured to output a nonsinusoidal signal to a load, at least one wideband sensor configured to measure at least one of a voltage and a current of the nonsinusoidal signal, and a controller coupled to the RF generator. The controller is configured to receive a waveform associated with the nonsinusoidal signal from the at least one wideband sensor, determine an uncalibrated value at each of a number of harmonic components of the waveform, and generate a calibrated value at each of the number of harmonic components based on the corresponding uncalibrated value and a frequency response of the at least one wideband sensor.

Implementations may include one or more of the following features. The waveform may be a voltage waveform. The calibrated value at each of the number of harmonic components may be a calibrated voltage value. The controller may be configured to receive a current waveform associated with the nonsinusoidal signal from the at least one wideband sensor, determine an uncalibrated current value at each of a number of harmonic components of the current waveform, and generate a calibrated current value at each of the number of harmonic components based on the corresponding uncalibrated value and a frequency response of the at least one wideband sensor. The controller may be configured to sample the waveform at a defined frequency, and determine the uncalibrated value at each of the number of harmonic components of the sampled waveform. The number of harmonic components may be twenty harmonic components. The controller may be configured to determine the uncalibrated value at each of the number of harmonic components of the waveform based on a Fourier analysis of the waveform. The calibrated value at each of the number of harmonic components may include a voltage or current magnitude and an associated phase. The controller may be configured to receive a chain matrix including parameters, and multiply the voltage or current magnitude at each of the number of harmonic components by one of the parameters of the chain matrix and the associated phase by another one of the parameters of the chain matrix to generate the calibrated value. The controller may be configured to determine at least one of active power and reactive power associated with the nonsinusoidal signal. The controller may be configured to control the RF generator based on the at least one of the active power and the reactive power. The controller may be configured to generate a warning based on the at least one of the active power and the reactive power. The nonsinusoidal signal may be a carrier signal. The RF generator may be controlled to pulse the carrier signal. The nonsinusoidal carrier signal may be at least one of a rectangular or piecewise linear waveform. The pulse may be one of a rectangular, trapezoidal, triangular, sawtooth, or gaussian pulse waveform. The pulse may include a plurality of states.

According to another aspect of the present disclosure, a nontransitory computer-readable medium storing processor-executable instructions is disclosed. The instructions include receiving, from at least one wideband sensor, a waveform associated with a nonsinusoidal signal, determining an uncalibrated value at each of a number of harmonic components of the waveform, and generating a calibrated value at each of the number of harmonic components based on the corresponding uncalibrated value and a frequency response of the at least one wideband sensor.

Implementations may include one or more of the following features. The instructions may include storing the calibrated value at each of the number of harmonic components. The instructions may include sampling the waveform at a defined frequency, and determining the uncalibrated value at each of the number of harmonic components of the sampled waveform. The instructions may include receiving a chain matrix including parameters, and multiplying components of the uncalibrated value at each of the number of harmonic components by the parameters of the chain matrix to generate the calibrated value. The instructions may include storing determining at least one of active power and reactive power associated with the nonsinusoidal signal, and controlling an RF generator to output a signal to a load based on the at least one of the active power and the reactive power.

According to another aspect of the present disclosure, a controller for a RF generator configured to output a nonsinusoidal signal to a load is disclosed. The controller includes a power controller configured to receive, from at least one wideband sensor, a waveform associated with a nonsinusoidal signal, determine an uncalibrated value at each of a number of harmonic components of the waveform, and generate a calibrated value at each of the number of harmonic components based on the corresponding uncalibrated value and a frequency response of the at least one wideband sensor.

Implementations may include one or more of the following features. The power controller may be configured to store the calibrated value at each of the number of harmonic components. The power controller may be configured to sample the waveform at a defined frequency, and determine the uncalibrated value at each of the number of harmonic components of the sampled waveform. The number of harmonic components may be ten or more harmonic components. The power controller may be configured to receive a chain matrix including parameters, and multiply components of the uncalibrated value at each of the number of harmonic components by the parameters of the chain matrix to generate the calibrated value. The power controller is configured to determine at least one of active power and reactive power associated with the nonsinusoidal signal, and control an RF generator to output a signal to a load based on the at least one of the active power and the reactive power.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings.

FIG. 1 shows a generalized representation of a plasma system arranged according to various configurations of the present disclosure;

FIG. 2 system a schematic block diagram of a power delivery system having multiple power supplies arranged according to various configurations of the present disclosure;

FIGS. 3A-B show waveforms of a time-varying signal and a pulse modulating the time-varying signal to describe a pulsed mode of operation;

FIGS. 3C-3E show various waveforms for DC carrier signals;

FIG. 4 shows a partial schematic block diagram of a power generation system for applying power to a load arranged according to various configurations of the present disclosure;

FIG. 5 shows a partial schematic block diagram of a power generation system including a controller for generating calibrated measurements of nonsinusoidal waveforms from a wideband sensor arranged according to various configurations of the present disclosure;

FIG. 6 shows nonsinusoidal waveforms for voltage and current from a wideband sensor and instantaneous power;

FIG. 7 shows a plot of an example frequency response of a wideband sensor;

FIG. 8 shows a functional block diagram of an example control module arranged in accordance with various configurations;

FIG. 9 shows a flow chart of operation of a control system arranged in accordance with the principles of the present disclosure; and

FIG. 10 shows another flow chart of operation of a control system arranged in accordance with the principles of the present disclosure.

In the drawings, reference numbers may be reused to identify similar and/or identical elements.

### DETAILED DESCRIPTION

A power system may include a DC or RF power generator or DC or RF generator, collectively referred to as generator or generators, a matching network, and a load (such as a process chamber, a plasma chamber, or a reactor having a fixed or variable impedance). The generator generates a DC power signal or a sinusoidal, RF, or other time-varying signal, which is received by the matching network or impedance optimizing controller or circuit. The matching network or impedance optimizing controller or circuit transforms a load impedance to a characteristic impedance of a transmission line between the generator and the matching network. Impedance matching aids in maximizing an amount of power delivered to the load (“delivered power”) and minimizing an amount of power reflected back from the load to the generator (“reverse power” or “reflected power”). Delivered power may be maximized by minimizing reflected power when the input impedance of the matching network matches the characteristic impedance of the transmission line and generator.

In the power source or power supply field, there are typically two approaches to applying a power signal to the load. A first, more traditional approach is to apply a continuous voltage, current, or power signal to the load. In a continuous mode or continuous wave mode, a continuous voltage, current, or power signal is typically a constant DC, sinusoidal, or periodic time-varying (e.g., nonsinusoidal and/or pulsed DC) signal, which may be a RF or other voltage, current, or power signal, that is output continuously by the power source to the load. In the continuous mode approach, the voltage, current, or power signal assumes a constant DC, sinusoidal, nonsinusoidal, or pulsed DC output, and the amplitude of the power signal and/or frequency (of a RF power signal) can be varied in order to vary the output power applied to the load.

A second approach to applying the power signal to the load involves pulsing a voltage, current, or power signal, rather than applying a continuous voltage, current, or power signal to the load. In a pulse or pulsed mode of operation, a voltage, current, or power signal or carrier signal is modulated by a modulation signal in order to define an envelope for the modulated power signal. The voltage, current, or power signal may be, for example, a sinusoidal RF signal or other periodic or nonperiodic time-varying signal. Power delivered to the load is typically varied by varying the modulation signal. In a pulsed mode of operation of a pulsed DC signal, the voltage, current, or power signal may be a periodic or nonperiodic DC signal that alternates between at least a first amplitude and a second amplitude over one or more cycles and modulated by a modulation signal in order to define an envelope for the pulsed DC signal. In various configurations, a transition between the first amplitude and the second amplitude may include various shapes, including vertical slopes, nonvertical slopes, or combinations thereof, stair steps, and the like. Further the transition between the first amplitude and the second, or the second amplitude and the first amplitude, may be consistent or vary from cycle.

In a typical power supply configuration, output voltage, current, or power applied to the load is determined using sensors that measure the forward and reflected voltage, current, or power signal. Either set of these signals is analyzed in a control loop. The analysis typically determines parameter or a cost function that varies in accordance with a voltage, current, or power value and is used to adjust the output of the power supply in order to vary the voltage, current, or power applied to the load. In a power delivery system where the load is a process chamber or other nonlinear or time-varying load, the varying impedance of the load causes a corresponding varying of voltage, current, or power applied to the load and consequent varying of the parameter or cost function, as applied voltage, current, or power is in part a function of the impedance of the load.

In systems where fabrication of various devices relies upon introduction of voltage, current, or power to a load to control a fabrication process, voltage, current, or power is typically delivered in one of two configurations. In a first configuration, voltage, current, or power is capacitively coupled to the load. Such systems are referred to as capacitively coupled plasma (CCP) systems. In a second configuration, the voltage, current, or power is inductively coupled to the load. Such systems are typically referred to as inductively coupled plasma (ICP) systems. Coupling to the plasma can also be achieved via wave coupling at microwave frequencies. Such an approach typically uses Electron Cyclotron Resonance (ECR) or microwave sources. Helicon sources are another form of wave coupled sources and typically operate at frequencies similar to that of conventional ICP and CCP systems. In various configurations, the Helicon sources may operate at RF frequencies. Power delivery systems may include at least one bias power and/or a source power applied to one or a plurality of electrodes of the load. The source power typically generates a plasma and controls plasma density, and the bias power modulates ions in the formulation of the sheath. The bias and the source may share the same electrode or may use separate electrodes, in accordance with various design considerations.

When a power delivery system drives a time-varying or nonlinear load, such as a process chamber or plasma chamber, the power absorbed by the bulk plasma and plasma sheath results in a density of ions with a range of ion energy. One characteristic measure of ion energy is the ion energy distribution function (IEDF). The ion energy distribution function (IEDF) can be controlled with the bias power or voltage. One way of controlling the IEDF for a system in which multiple voltage, current, or power signals are applied to the load occurs by varying multiple voltage, current, or power signals that are related by at least one of amplitude, frequency, and phase. The related at least one of amplitude, frequency, and phase of multiple voltage, current, or power signals may also be related by a Fourier series and the associated coefficients. The frequencies between the multiple voltage, current, or power signals may be locked, and the relative phase between the multiple voltage, current, or signals may also be locked. Examples of such systems can be found with reference to U.S. Pat. No. 7,602,127, issued Oct. 13, 2009; U.S. Pat. No. 8,110,991, issued Feb. 7, 2012; and U.S. Pat. No. 8,395,322, issued Mar. 12, 2013, all entitled Phase and Frequency Control of a Radio Frequency Generator from an External Source, assigned to the assignee of the present application, and incorporated by reference herein.

Time varying or nonlinear loads may be present in various applications. In one application, plasma processing systems may also include components for plasma generation and control. One such component is a nonlinear load implemented as a process chamber, such as a plasma chamber or reactor. A typical plasma chamber or reactor utilized in plasma processing systems, such as by way of example, for thin-film manufacturing, can utilize a dual power system. One voltage, current, or power generator (the source) controls the generation of the plasma, and the other voltage, current, or power generator (the bias) controls ion energy. Examples of dual power systems include systems that are described in U.S. Pat. Nos. 7,602,127; 8,110,991; and 8,395,322, referenced above. The dual power system described in the above-referenced patents employs a closed-loop control system to adapt power supply operation for the purpose of controlling ion density and its corresponding ion energy distribution function (IEDF).

Multiple approaches exist for controlling a process chamber, such as may be used for generating plasmas. For example, in voltage, current, or power delivery systems, phase and frequency of multiple driving signals operating at the same or nearly the same frequency may be used to control plasma generation. For such driven plasma sources, the periodic waveform affecting plasma sheath dynamics and the corresponding ion energy are generally known and are controlled by the frequency of the periodic waveforms and the associated phase interaction. Another approach in voltage, current, or power delivery systems involves dual frequency control. That is, two frequency sources operating at different frequencies are used to power a plasma chamber to provide substantially independent control of ion and electron densities. In various configurations, the frequency may be a RF frequency.

Another approach utilizes wideband RF power sources to drive a plasma chamber. A wideband approach presents certain challenges. One challenge is coupling the power to the electrode. A second challenge is that the transfer function of the generated waveform to the actual sheath voltage for a desired IEDF must be formulated for a wide process space to support material surface interaction. In one responsive approach in an inductively coupled plasma system, controlling power applied to a source electrode controls the plasma density while controlling power applied to the bias electrode modulates ions to control the IEDF to provide etch rate and etch feature profile control. By using source electrode and bias electrode control, the etch rate and other various etch characteristics are controlled via the ion density and energy.

As integrated circuit and device fabrication continues to evolve, so do the power requirements for controlling the process for fabrication. For example, with memory device fabrication, the requirements for bias voltage, current, or power continue to increase. Increased voltage, current, or power generates higher and more energetic ions for increased directionality or anisotropic etch feature profiles and faster surface interaction, thereby increasing the etch rate and allowing higher aspect ratio features to be etched. In one nonlimiting example, in some voltage, current, or power delivery systems, increased ion energy is sometimes accompanied by a lower bias frequency requirement along with an increase in the power and number of bias power sources coupled to the plasma sheath created in the plasma chamber. The increased power at a lower bias frequency and the increased number of bias power sources results in intermodulation distortion (IMD) from sheath modulation. The IMD emissions can significantly reduce power delivered by the source where plasma generation occurs. U.S. Pat. No. 10,821,542, issued Nov. 3, 2020, entitled Pulse Synchronization by Monitoring Power in Another Frequency Band, assigned to the assignee of the present application, and incorporated by reference herein, describes a method of pulse synchronization by monitoring power in another frequency band. In the referenced U.S. patent application, the pulsing of a second RF generator is controlled in accordance with detecting at the second RF generator the pulsing of a first RF generator, thereby synchronizing pulsing between the two RF generators.

In more specific instances of integrated circuit and device fabrication, the manufacture of high performance memory and logic devices, such as three dimensional NAND (3D NAND) flash memory and Dynamic Random Access Memory (DRAM) requires precise etching of extremely high aspect ratio (HAR) features with high selectivity of a target material to a etch mask. HAR features typically have a height to width ratio (height:width) ratio of greater than 50:1 (>50:1). To manufacture such devices, a processing system used for HAR etching may rely on a pulsed DC or nonsinusoidal bias power source or generator. In such examples, the bias power source or generator provides a high voltage, current, or power, pulsed DC signal or nonsinusoidal carrier waveform and envelope modulates the waveform at a lower frequency. For example, the bias power source or generator may provide high voltage shaped pulses from 100V to over 20 kV. The pulsed DC bias waveform is used to create a monoenergetic IEDF. The modulation of this waveform is used to alternate between high energy ion-assisted etching of the devices and low energy polymer formation to protect the HAR feature sidewalls.

Often, measurement and control of carrier waveforms are inaccurate and not repeatable. For example, when carrier waveforms are nonsinusoidal, the waveforms include several Fourier frequency components over several octaves of bandwidth (e.g., over a wide range of harmonics). While wideband sensors (e.g., voltage and current sensors) may be used for measuring and controlling such carrier waveforms, measurement and control with such wideband sensors may be inaccurate and/or not repeatable from one system to another system.

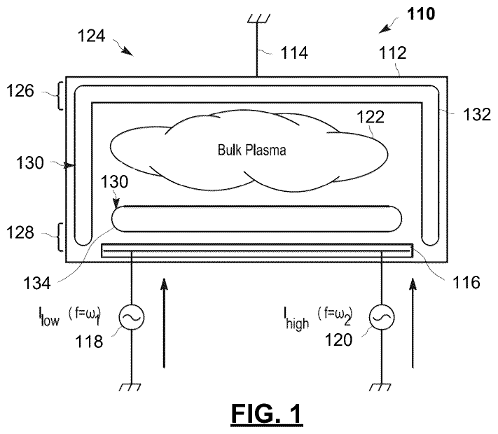

FIG. 1 depicts a cross-sectional view of a generalized representation of a dual voltage, current, or power input plasma system 110. Plasma system 110 includes first electrode 112 connected to ground 114 and second electrode 116 spaced apart from first electrode 112. A first power source 118 generates a first voltage, current, or power signal as described above applied to second electrode 116 at a first frequency f=ω₁. A second power source 120 generates a second DC (ω=0) or sinusoidal voltage, current, or power applied to second electrode 116. In various configurations, second power source 120 operates at a second frequency f=ω₂, where ω₂=nω that is the n^{th} harmonic frequency of the frequency of first power source 118. In various other configurations, second power source 120 operates at a frequency that is not a multiple of the frequency of the first power source 118.

Coordinated operation of respective power sources 118, 120 results in generation and control of plasma 122. As shown in FIG. 1 in schematic view, plasma 122 is formed within an asymmetric sheath 130 of plasma chamber 124. Sheath 130 includes a ground or grounded sheath 132 and a powered sheath 134. A sheath is generally described as the surface area surrounding plasma 122. As can be seen in schematic view in FIG. 1, grounded sheath 132 has a relatively large surface area 126. Powered sheath 134 has a small surface area 128. Because each sheath 132, 134 functions as a dielectric between the conductive plasma 122 and respective electrodes 112, 116, each sheath 132,134 forms a capacitance between plasma 122 and respective electrodes 112, 116.

As will be described in greater detail herein, in systems in which a high frequency voltage, current, or power source, such as second power source 120, and a low frequency voltage, current, or power source, such as first power source 118, intermodulation distortion (IMD) products are introduced. IMD products result from a change in plasma sheath thickness, thereby varying the capacitance between plasma 122 and electrode 112, via grounded sheath 132, and plasma 122 and electrode 116, via powered sheath 134. The variation in the capacitance of powered sheath 134 generates IMD. Variation in powered sheath 134 has a greater impact on the capacitance between plasma 122 and electrode 116 and, therefore, on the reverse IMD emitted from plasma chamber 124. In some plasma systems grounded sheath 132 acts as a short circuit and is not considered for its impact on reverse IMD.

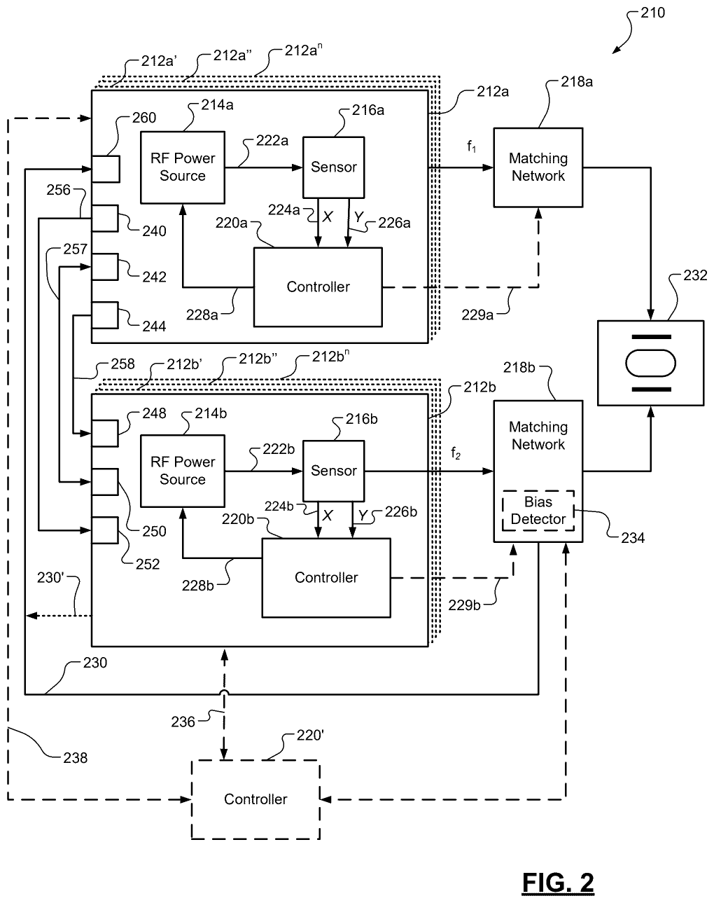

FIG. 2 depicts a RF generator or power supply system 210. Power supply system 210 includes a pair of radio frequency (RF) generators or power supplies 212a, 212b, matching networks 218a, 218b, and load 232, such as a nonlinear load, which may be a plasma chamber, plasma reactor, process chamber, and the like. In various configurations, generator 212a is referred to as a source generator or power supply, and matching network 218a is referred to as a source matching network. Further, in various configurations, one or both of voltage current, or power generators or power supplies 212a, 212b may output a continuous or pulsed time-varying voltage, current, or power signal or a continuous or pulsed DC voltage, current, or power signal. Also in various configurations, generator 212b is referred to as a bias generator or power supply, and matching network 218b is referred to as a bias matching network. It will be understood that components can be referenced individually or collectively using the reference number with or without a letter subscript or a prime symbol. In various configurations, one or both of matching networks 218a, 218b may be implemented as a RF blocking filter, rather than an impedance match, such as may be the case for a matching network receiving a pulsed DC or nonsinusoidal signal. In various other configurations, one or both of matching networks 218a, 218b may be omitted.

In various configurations, source generator 212a receives a control signal 230 from matching network 218b, generator 212b, or a control signal 230′ from bias generator 212b. Control signals 230 or 230′ represent an input signal to source generator 212a that indicates one or more operating characteristics or parameters of bias generator 212b. In various configurations, a synchronization bias detector 234 senses the signal output from matching network 218b to load 232 and outputs synchronization or trigger signal 230 to source generator 212a. In various configurations, synchronization or trigger signal 230′ may be output from bias generator 212b to source RF generator 212a, rather than trigger signal 230. A difference between trigger or synchronization signals 230, 230′ may result from the effect of matching network 218b, which can adjust the phase between the input signal to and output signal from matching network. Signals 230, 230′ include information about the operation of bias RF generator 212b that in various configurations enables predictive responsiveness to address periodic fluctuations in the impedance of plasma chamber or load 232 caused by the bias generator 212b. When control signals 230 or 230′ are absent, generators 212a, 212b operate autonomously.

Generators 212a, 212b include respective power sources or amplifiers 214a, 214b, sensors 216a, 216b, and processors, controllers, or control modules 220a, 220b. Power sources 214a, 214b generate respective voltage, current, or power signals 222a, 222b, various configurations of which are described above, output to respective sensors 216a, 216b. RF power signals 222a, 222b. Signals 222a, 222b pass through sensors 216a, 216b and are provided to matching networks 218a, 218b as respective power signals f₁ and f₂. Sensors 216a, 216b output signals that vary in accordance with various parameters sensed from load 232. While sensors 216a, 216b, are shown within respective generators 212a, 212b, sensors 216a, 216b can be located externally to generators 212a, 212b. Such external sensing can occur at the output of the generator, at the input of an impedance matching device located between the generator and the load, or between the output of the impedance matching device (including within the impedance matching device) and the load.

In various embodiments, one or more additional sensors may be added to power supply system 210. For example, an additional sensor may be within generator 212a (or generator 212b) or located externally to generator 212a (or generator 212b). In such examples, the additional sensor may be coupled in series with sensor 216a (or sensor 216b) and generally function in a similar manner as sensors 216a, 216b. For instance, the additional sensor may detect various operating parameters, store data relating to the operating parameters, and output data.

In various embodiments, the additional sensor may be part of a detector module. In such examples, the detector module may include the additional sensor and a respective controller or control module. In various embodiments, the detector may be employed to calibrate sensors 216a, 216b and confirm desired operation of components of power supply system 210, such as sensors 216a, 216b, generators 212a, 212b, etc. In some examples, the detector and/or the additional sensor may be a standalone or retrofit component that is inserted into and/or removed from power supply system 210.

Sensors 216a, 216b detect various operating parameters and output signals X and Y. Sensors 216a, 216b may include voltage, current, and/or directional coupler sensors. Sensors 216a, 216b may detect (i) voltage V and current I and/or (ii) forward power P_{FWD} output from respective power amplifiers 214a, 214b and/or RF generators 212a, 212b and reverse or reflected power P_{REV} received from respective matching networks 218a, 218b or load 232 connected to respective sensors 216a, 216b. The voltage V, current I, forward power P_{FWD}, and reverse power P_{REV} may be scaled, filtered, or scaled and filtered versions of the actual voltage, current, forward power, and reverse power associated with the respective power sources 214a, 214b. Sensors 216a, 216b may be analog or digital sensors or a combination thereof. In a digital implementation, the sensors 216a, 216b may include analog-to-digital (A/D) converters and signal sampling components with corresponding sampling rates. Signals X and Y can represent any of the voltage V and current I or forward (or source) power P_{FWD} reverse (or reflected) power P_{REV}.

Sensors 216a, 216b generate sensor signals X, Y, which are received by respective controllers or control modules 220a, 220b. Control modules 220a, 220b process the respective X, Y signals 224a, 226a and 224b, 226b and generate one or a plurality of feedforward or feedback control signals 228a, 228b to respective power sources 214a, 214b. Power sources 214a, 214b adjust voltage, current, or power signals 222a, 222b based on the received one or plurality feedback or feedforward control signal. In various configurations, control modules 220a, 220b may control matching networks 218a, 218b, respectively, via respective control signals 2229a, 2229b based on, for example, X, Y signals 224a, 226a and 224b, 226b. Control modules 220a, 220b may include one or more proportional-integral (PI), proportional-integral-derivative (PID), linear-quadratic-regulator (LQR) controllers or subsets thereof and/or direct digital synthesis (DDS) component(s) and/or any of the various components described below in connection with the modules.

In various configurations, control modules 220a, 220b may include functions, processes, processors, or submodules. Control signals 228a, 228b may be control or actuator drive signals and may communicate DC offset or rail voltage, voltage or current magnitude, frequency, and phase components, and the like. In various configurations, feedback control signals 228a, 228b can be used as inputs to one or multiple control loops. In various configurations, the multiple control loops can include a proportional-integral (PI), proportional-integral-derivative (PID) controllers, linear-quadratic-regulator (LQR) control loops, or subsets thereof, for RF drive, and for power supply rail voltage. In various configurations, control signals 228a, 228b can be used in one or both of a single-input-single-output (SISO) or multiple-input-multiple-output (MIMO) control scheme. An example of a MIMO control scheme can be found with reference to U.S. Pat. No. 10,546,724, issued on Jan. 28, 2020, entitled Pulsed Bidirectional Radio Frequency Source/Load, assigned to the assignee of the present application, and incorporated by reference herein. In other configurations, signals 228a, 228b can provide feedforward control as described in U.S. Pat. No. 10,049,857, issued Aug. 14, 2018, entitled Adaptive Periodic Waveform Controller, assigned to the assignee of the present application, and incorporated by reference herein.

In various configurations, power supply system 210 can include controller 220′. Controller 220′ may be disposed externally to either or both of generators 212a, 212b and may be referred to as external or common controller 220′. In various configurations, controller 220′ may implement one or a plurality of functions, processes, or algorithms described herein with respect to one or both of controllers 220a, 220b. Accordingly, controller 220′ communicates with respective generators 212a, 212b via a pair of respective links 236, 238 which enable exchange of data and control signals, as appropriate, between controller 220′ and generators 212a, 212b. For the various configurations, controllers 220a, 220b, 220′ can distributively and cooperatively provide analysis and control of generators 212a, 212b. In various other configurations, controller 220′ can provide control of generators 212a, 212b, eliminating the need for the respective local controllers 220a, 220b.

In various configurations, power source 214a, sensor 216a, controller 220a, and matching network 218a can be referred to as source RF power source 214a, source sensor 216a, source controller 220a, and source matching network 218a, respectively. Similarly in various configurations, RF power source 214b, sensor 216b, controller 220b, and matching network 218b can be referred to as bias power source 214b, bias sensor 216b, bias controller 220b, and bias matching network 218b, respectively. In various configurations and as described above, the source term refers to the generator or voltage, current, or power source that generates a plasma, and the bias term refers to the generator or voltage, current, or power source that tunes ion potential and the Ion Energy Distribution Function (IEDF) of the plasma. In various configurations, the source and bias power supplies operate at different frequencies or duty cycles. In various configurations, the source power supply operates at a higher frequency or duty cycle than the bias power supply. In various other configurations, the source and bias power supplies operate at the same frequencies or duty cycles or substantially the same frequencies or duty cycles.

According to various configurations, in addition to or by way of partial or total substitution to the synchronization signals described above with respect to signals 230, 230′, source generator 212a and bias generator 212b include multiple ports to communicate with each other and with external devices. Source generator 212a includes pulse synchronization port 240, communication port 242, RF port 244, and control signal port 260. Bias generator 212b includes RF port 248, communication port 250, and pulse synchronization port 252. Pulse synchronization port 240 of source generator 212a communicates pulse synchronization signals via link 256 with pulse synchronization port 252 of bias generator 212b. Communication port 242 of source generator 212a and communication port 250 of bias generator 212b communicate data and information via a communication link 257. RF port 244 of source generator 212a communicates with RF port 248 via communication link 258. Control signal port 260 of source generator 212a receives one or both of control signals 230, 230′, as described above. In various configurations, one or more of the ports described above may communicate with matching network 218 for communicating sensed or control signals, as may be described herein.

In various configurations, communication between pulse synchronization port 240 and pulse synchronization port 252 may be unidirectional or bidirectional between source generator 212a and bias generator 212b. In various configurations, one of source generator 212a and bias generator 212b communicate, by way of nonlimiting example, envelope pulse information to the other of bias generator 212b and source generator 212a. In various configurations, one or multiple communication links 256 link pulse synchronization port 240 and pulse synchronization port 252. In various configurations, communication between pulse synchronization port 240 and pulse synchronization port 252 may occur via analog or digital communication.

In various configurations, communication between communication port 242 of source generator 212a and communication port 250 of bias generator 212b may be unidirectional or bidirectional between source generator 212a and bias generator 212b. In various configurations, communication port 242 of source generator 212a and communication port 250 of bias generator 212b communicate, by way of nonlimiting example, data, information, or synchronization signals. In various configurations, one or multiple communication links 257 link pulse synchronization port 242 and pulse synchronization port 250 In various configurations, communication between pulse synchronization port 242 and pulse synchronization port 250 may occur via analog or digital communication.

In various configurations, communication between RF port 244 of source generator 212a and RF port 248 of bias generator 212b may be unidirectional or bidirectional between source generator 212a and bias generator 212b. In various configurations, RF port 244 of source generator 212b and RF port 248 of bias generator 212b communicate, by way of nonlimiting example, a signal indicating one or more of voltage, current, or power output by the respective generator. By way of nonlimiting example, time-varying RF signals, such as sinusoidal voltage, current, or power signals may be communicated. In various configurations, one or multiple communication links 258 link signal port 244 and signal port 248. In various configurations, communication between signal port 244 and signal port 248 may occur via analog or digital communication.

In various configurations, a control signal communicated via communications link 258 is substantially the same as the control signal controlling source generator 212a. In various other configurations, the control signal communicated via communications link 258 is the same as the control signal controlling source generator 212a, but is phase shifted within source generator 212a in accordance with a requested phase shift generated by bias generator 212b. Thus, in various configurations, source generator 212a and bias generator 212b are driven by substantially identical control signals or by substantially identical control signals phase shifted by a predetermined amount.

In various configurations, power supply system 210 may include multiple source generators 212a and multiple bias generators 212b. By way of nonlimiting example, a plurality of source generators 212a, 212a′, 212a″, . . . , 212an can be arranged to provide a plurality of output power signals to one or more source electrodes of load 232. Similarly, a plurality of bias generators 212b, 212b′, 212b″, . . . , 212bn may provide a plurality of output power signals to a plurality of bias electrodes of load 232. When source generator 212a and bias generator 212b are configured to include a plurality of respective source generators or bias generators, each generator will output a separate signal to a corresponding plurality of matching networks 218a, 218b, configured to operate as described above, in a one-to-one correspondence. In various other configurations, there may not be a one-to-one correspondence between each generator and matching network. In various configurations, multiple source electrodes may refer to multiple electrodes that cooperate to define a composite source electrode. Similarly, multiple bias electrodes may refer to multiple connections to multiple electrodes that cooperate to define a composite bias electrode.

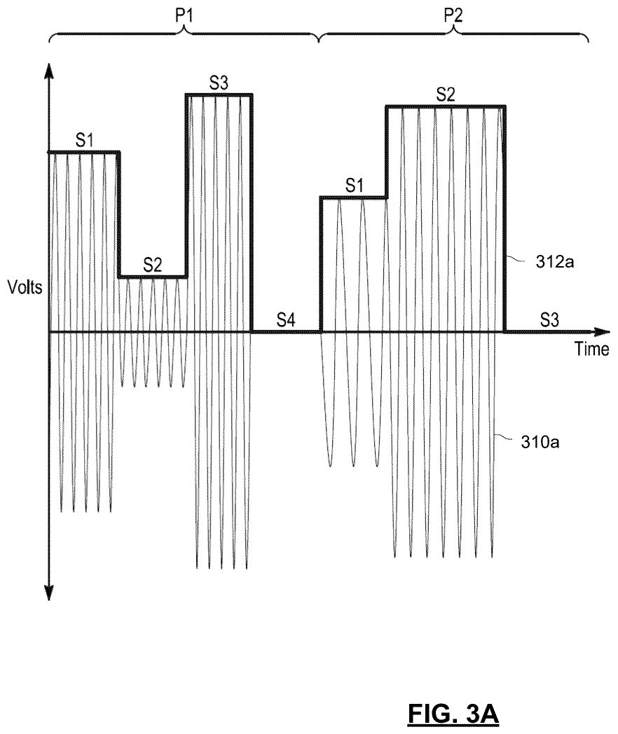

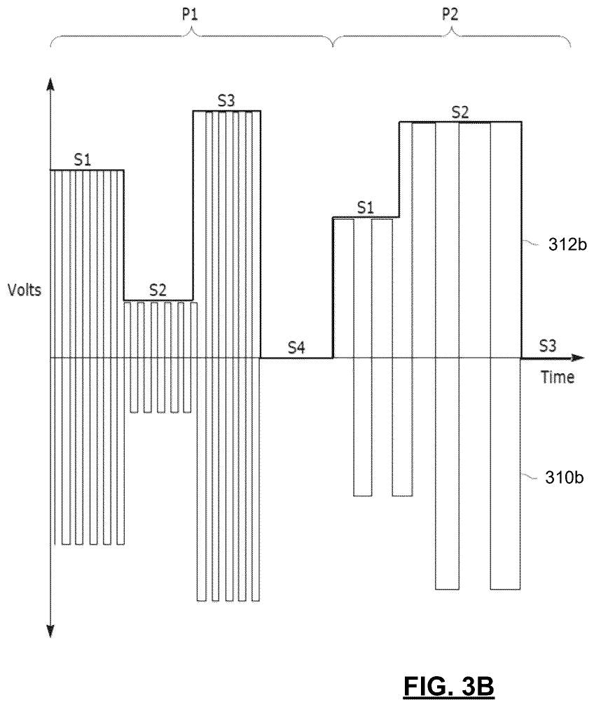

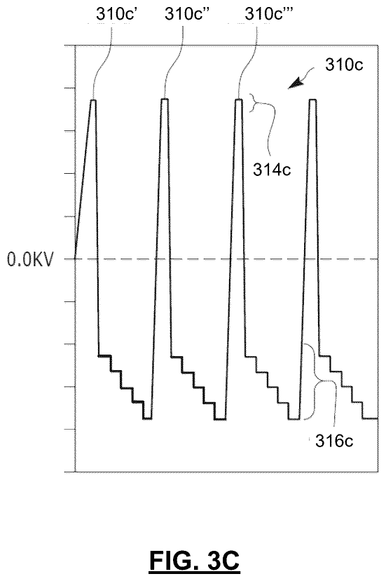

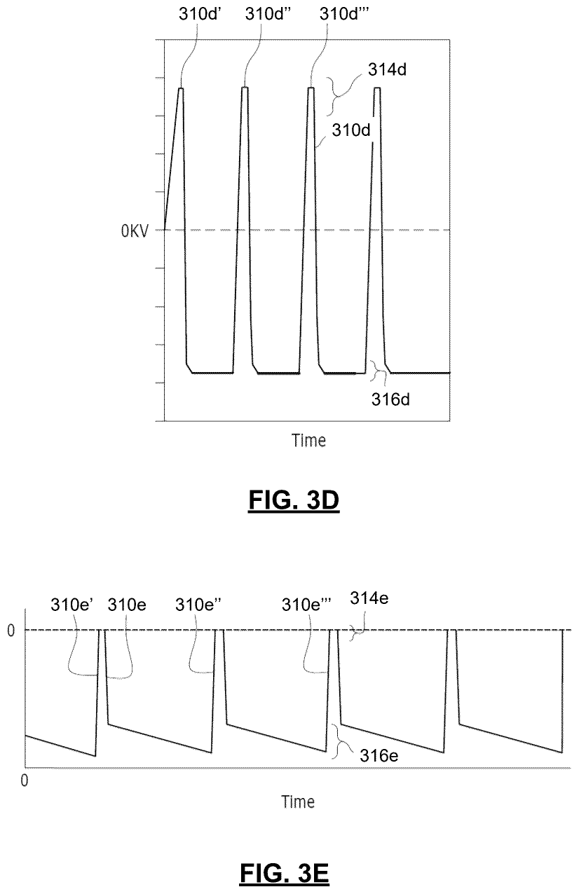

FIG. 3A depicts a plot of voltage versus time to describe a pulse or pulsed mode of operation for delivering voltage, current, or power to a load, such as load 232 of FIG. 2. More particularly, FIG. 3A depicts signal or waveform 310a, which, by way of nonlimiting example, is depicted as a sinusoidal signal or waveform. Waveform 310a may be referred to as a carrier waveform or carrier signal. Two-multistate pulses P1, P2 of an envelope or pulse signal 312a having respective states S1-S4 and S1-S3 modulate waveform 310a. As shown at states S1-S3 of P1 and S1-S2 of P2, when the pulses are ON, RF generator 212 outputs RF signal as waveform 310a having an amplitude defined by the pulse magnitude of each state. Conversely, during states S4 of P1 and S3 of P2, the pulses are OFF, and generator 212 does not output waveform 310a. Pulses P1, P2 can repeat at a constant duty cycle or a variable duty cycle, and states S1-S4, S1-S3 of each respective pulse P1, P2 may have the same or varying amplitudes and widths. In various configurations, waveform 310a may be implemented as a RF or other than RF waveform and may be a sinusoidal or nonsinusoidal waveform. Further, the frequency of waveform may vary between or within states S1-S4, S1-S3 and between or within pulses P1, P2.

FIG. 3B depicts a plot of voltage versus time to describe an alternative pulse or pulsed mode of operation for delivering voltage, current, or power to a load, such as load 232 of FIG. 2. FIG. 3B depicts signal or waveform 310b, which, by way of nonlimiting example, is depicted as a square wave signal or waveform. Waveform 310b may be referred to as a pulsed DC signal or waveform or a DC carrier signal or waveform. Two-multistate pulses P1, P2 of an envelope or pulse signal 312b having respective states S1-S4 and S1-S3 modulate waveform 310b. Waveform 310b is shown as a nonsinusoidal, periodic signal or waveform modulated by pulses P1 and P2. Waveform 310b may be a signal that pulses or oscillates between a first amplitude and a second amplitude over one or more cycles with various transitions therebetween. At least one of the first and second amplitudes may vary over time in accordance with envelope or pulse signal 312b. As shown at states S1-S3 of P1 and S1-S2 of P2, when the pulses are ON, RF generator 212 outputs waveform 310b having an amplitude defined by the pulse magnitude of each state. Conversely, during states S4 of P1 and S3 of P2, the pulses are OFF, and generator 212 does not output waveform 310b. Thus, modulating signal or waveform 310b (pulsed DC signal or waveform) with envelope or pulse signal 312b provides a pulse-within-a-pulse effect. Pulses P1, P2 can repeat at a constant duty cycle or a variable duty cycle, and states S1-S4, S1-S3 of each respective pulse P1, P2 may have the same or varying amplitudes and widths. In various configurations, while waveform 310b of FIG. 3B is shown as a square wave, waveform 310b need not be implemented as a conventional square wave. The first and second amplitudes of waveform 310b may be flat, sloping, or peaked, and the transitions between the first and second amplitudes may include linear slopes, stairsteps, other shapes, or combinations thereof.

FIG. 3C shows one nonlimiting example of a pulsed DC carrier signal 310c having cycles 310c′, 310c″, 310c′″. Pulsed DC signal 310c includes high amplitudes 314c of cycles 310c′, 310c″, 310c′″ and low amplitudes 316c of cycles 310c′, 310c″, 310c′″. As shown in FIG. 3C, high amplitudes 314c are generally flat. Low amplitudes 316c have a stairstep transition, which may result from selected power amplifiers transitioning negatively or low sequentially. In various configurations, the stairstep transition of low amplitudes 316c provides improved slope compensation.

FIG. 3D shows one nonlimiting example of a pulsed DC carrier signal 310d having cycles 310d′, 310d″, 310d′″. Pulsed DC signal 310d includes high amplitude 314d of cycles 310d′, 310d″, 310d′″ and low amplitudes 316d of cycles 310d′, 310d″, 310d′″. As shown in FIG. 3D, high amplitudes 314d are generally flat. Low amplitudes 316d have a rounded shape at the transition from descending to generally constant, which may result from selected power amplifiers transitioning negatively or low sequentially with limited delay between each power amplifier transition. In various configurations, the pattern of low amplitudes 316d may improve ringing and overshoot.

FIG. 3E shows one nonlimiting example of a pulsed DC carrier signal 310e having cycles 310e′, 310e″, 310e′″. Pulsed DC signal 310e includes high amplitudes 314e of cycles 310e′, 310e″, 310e′″ and low amplitudes 316e of cycles 310e′, 310e″, 310e′″. As shown in FIG. 3E, high amplitudes 314e are generally constant. Low amplitudes 316e include a linear transition which results from piecewise linear control of DC carrier signal 310e. By way of nonlimiting example, in various configurations, DC carrier signal 310e may be a piecewise linear waveform as described in U.S. Pat. No. 10,396,601.

In various configurations, pulse signal 312 may be other than a square wave as shown in FIGS. 3A, 3B. Further, by way of nonlimiting example, envelope or pulse signal 312 may be a single or multistate rectangular, trapezoidal, triangular, sawtooth, gaussian, or other shape that defines an envelope or modulating envelope of the underlying, modulated, carrier signal 310.

In various configurations, carrier signal 310 may occur or reoccur periodically or nonperiodically within fixed or variable periods or time periods. In various other configurations, carrier signal 310 may vary in shape between each occurrence. Signal 310 may operate at frequencies that vary between states or within a state. In various other configurations, pulse signal 312 may occur or reoccur within fixed or variable time periods and vary in shape between each occurrence. Further yet, pulses P1, P2 can have multiple states S1, . . . , Sn of varying amplitude, duration, and shape. States S1, . . . , Sn may repeat within fixed or variable periods and may include all or a portion of the various shapes described above.

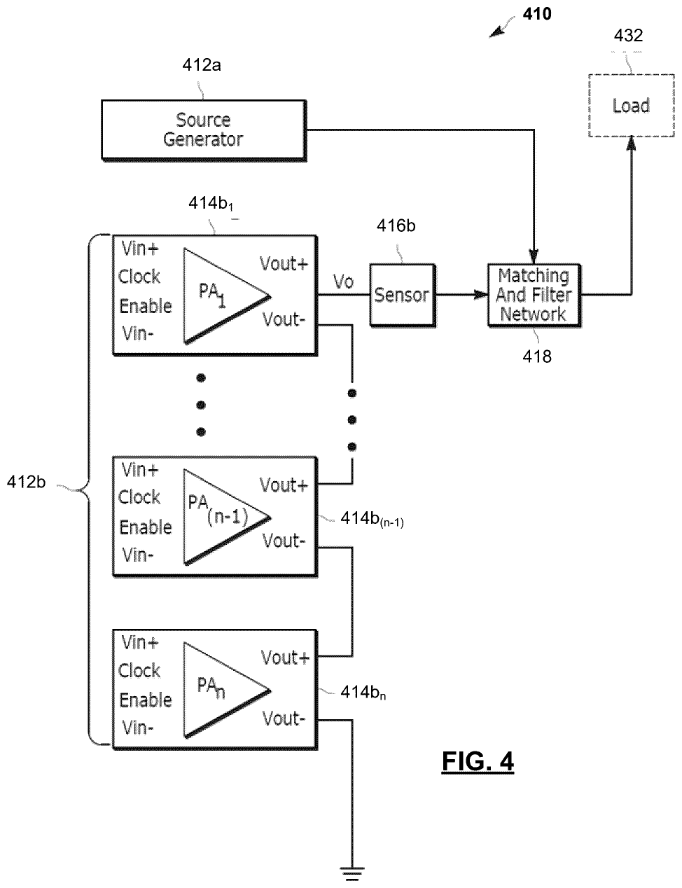

In various embodiments, a pulsed DC bias generator having series-connected power amplifier modules may be implemented to provide a high voltage, current, or power, pulsed DC signal or nonsinusoidal carrier waveform for use in HAR etching applications, as explained herein. For example, FIG. 4 shows a power generation system 710 that may be employed in HAR etching applications and/or other suitable applications.

As shown in FIG. 4, power generation system 710 uses a pulsed DC bias generator having series-connected power amplifier modules. For example, power generation system 710 includes a source generator 412a and a bias generator 412b. As shown, bias generator 412b includes a plurality, n in the nonlimiting example of FIG. 4, of power amplifier modules 414b₁, . . . , 414b₍ₙ₋₁₎, 414bₙ. Source generator 412a outputs a source signal to matching and filter network 418. Power amplifier modules 414b₁, . . . , 414b₍ₙ₋₁₎, 414bₙ of bias generator 414b are configured in series so that the series addition of the respective outputs defines a bias signal input to sensor 416b.

Source generator 412a shown in FIG. 4 represents a portion or the entirety of generator 212a of FIG. 2. Similarly, bias generator 412b shown in FIG. 4 represents a portion or the entirety of generator 212b of FIG. 2. Source generator 412a and bias generator 412b may include a power source 214, a sensor 216, and controller 220, not all of which may be shown in FIG. 4 and the following figures, but are shown in FIG. 2. Various control aspects implemented by controller 220 may be implemented via a standalone controller or be implemented via a common controller, such as controller 220′ of FIG. 2.

Sensor 416b of FIG. 4 is a wideband sensor, such as a voltage/current sensor or a directional coupler as described above, depending upon the desired parameters to be measured. Sensor 416b of FIG. 4 represents a portion or the entirety of sensor 216b of FIG. 2. In other examples, sensor 416b may represent a portion or the entirety of a detector module as explained above. Sensor 416b passes the bias signal through to matching and filter network 418. In various configurations, matching and filter network 418 provides a matching function, as described above. In various configurations, matching and filter network 418 provides isolation between source generator 412a and bias generator 412b. In various configurations, matching and filter network 418 may be implemented as individual matching networks, such as matching network 218a and matching network 218b of FIG. 2. The output from matching and filter network 418 is input to load 432, which may be configured as a load as described above.

Power amplifier modules 414b₁, . . . , 414b₍ₙ₋₁₎, 414bₙ are configured in series so that the outputs of each power amplifier module 414b₁, . . . , 414b₍ₙ₋₁₎, 414bₙ are added in order to generate a combined output applied to sensor 416b. In various configurations, power amplifier modules 414b₁, . . . , 414b₍ₙ₋₁₎, 414bₙ are controlled via a common or individual controller (not shown in FIG. 4). In a common controller configuration, control may be provided by any one or combination of controllers, such as controllers 220a, 220b, or 220′ of FIG. 2. In various configurations, each power amplifier module 414b₁, . . . , 414b₍ₙ₋₁₎, 414bₙ includes a respective power amplifier PA₁, . . . , PA₍ₙ₋₁₎, PAₙ, and each respective power amplifier PA₁, . . . , PA₍ₙ₋₁₎, PAₙ outputs one of three output voltages, +V_{PA}, −V_{PA}, and 0 volts. In other examples, any one or more of power amplifier modules 414b₁, . . . , 414b₍ₙ₋₁₎, 414bₙ may include a power amplifier module configured to output a piecewise linear voltage waveform instead of one of the three output voltages mentioned above.

In various configurations, power amplifier modules 414b₁, . . . , 414b₍ₙ₋₁₎, 414bₙ receive respective positive supply voltage signal Vᵢₙ+ and negative supply voltage signal Vᵢₙ− that define a rail voltage, where Vᵢₙ− may be chassis or floating ground. The magnitude of the difference between the Vᵢₙ+ and Vᵢₙ− voltage signals determines the magnitude of the +V_{PA} and −V_{PA} output voltages.

In FIG. 4, the supply voltage signal Vᵢₙ+ for each power amplifier module 414b₁, . . . , 414b₍ₙ₋₁₎, 414bₙ may be fixed and the same. In other examples, to control the amplitude of multistate pulses, additional power amplifier modules that have a different supply voltage than the fixed step power amplifier modules 414b₁, . . . , 414b₍ₙ₋₁₎, 414bₙ of FIG. 4 can be inserted into the series connection of power amplifiers. In such examples, one or more of the power amplifier modules may include a fixed generation section while one or more of other power amplifier modules may include a variable generation section. Additionally, in some examples, the supply voltage signal Vᵢₙ+ may be different for some of the power amplifier modules 414b₁, . . . , 414b₍ₙ₋₁₎, 414bₙ. For example, some of the power amplifier modules 414b₁, . . . , 414b₍ₙ₋₁₎, 414bₙ may operate at rail voltages +Vin/2, −Vin/2; +Vin/4, −Vin/4; . . . ; +Vin/2n, −Vᵢₙ/2n.

In various configurations, actuation of power amplifier modules 414b₁, . . . , 414b₍ₙ₋₁₎, 414bₙ is synchronized using a clock signal, as shown in FIG. 4. In various configurations, the individual ones of power amplifier modules 414b₁, . . . , 414b₍ₙ₋₁₎, 414bₙ are actuated or deactuated and the voltage output by a respective power amplifier is determined by an enable signal. The enable signal determines whether a power amplifier PAₓ is actuated and also determines the output voltage, +V_{PA}, −V_{PA}, or 0 volts, of power amplifier PAₓ. In various configurations, the enable signal, while shown as a single input to each amplifier module 414b₁, . . . , 414b₍ₙ₋₁₎, 414bₙ of FIG. 4, can represent a plurality of signals to control individual components of a respective power amplifier PAₓ. In various configurations, the enable signal may be considered as drive signals for the individual components of power amplifier PAₓ.

In various configurations, for n power amplifier modules, the clock signal synchronizes operation of the individual power amplifier modules 414b₁, . . . , 414b₍ₙ₋₁₎, 414bₙ, and the enable signal determines which of the n power amplifier modules 414b₁, . . . , 414b₍ₙ₋₁₎, 414bₙ are actuated and the output voltage of each power amplifier module 414b₁, . . . , 414b₍ₙ₋₁₎, 414bₙ. The synchronization provided by the clock signal provides for uniform transitions of the voltage signal to provide a output voltage V0 having pulse state changes with generally vertical transitions. If a predetermined number of power amplifier modules, m power amplifier modules for m less than n, by way of nonlimiting example, are actuated, the output of bias generator 412b may be a maximum voltage (m(+V_{PA})) and a minimum voltage (m(−V_{PA})). To achieve a maximum voltage output or minimum output voltage of bias generator 412b, all n power amplifier modules may be actuated to output a maximum voltage (n(+V_{PA})) or a minimum voltage (n(−V_{PA})).

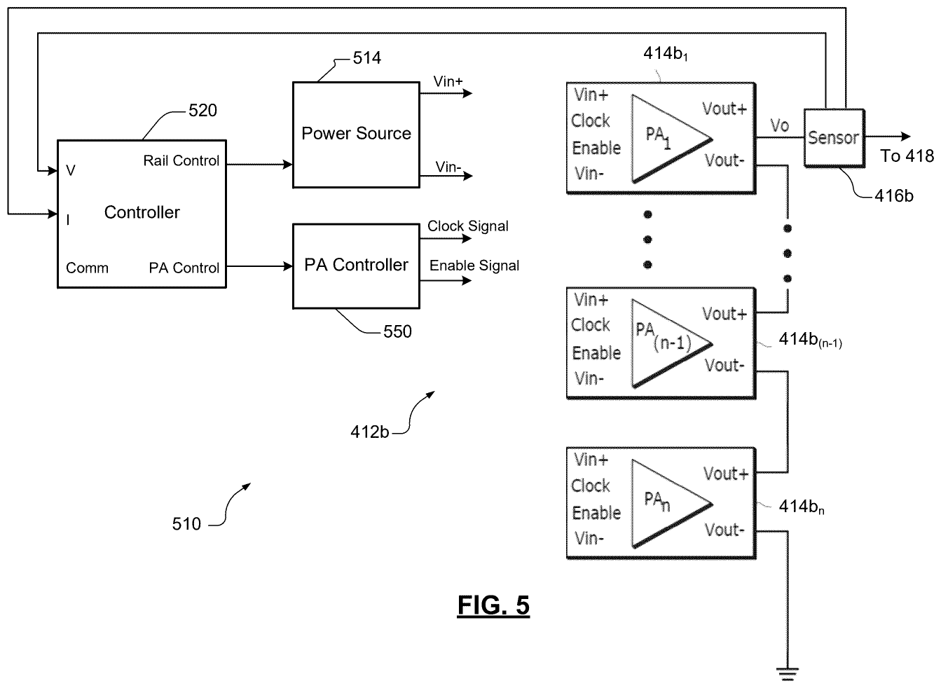

FIG. 5 shows a power generation system 510 similar to power generation system 410 of FIG. 4, but including various control and power components. For example, power generation system 510 of FIG. 5 is shown as including a power source 514, such as a power supply for providing the rail voltage (e.g., positive supply voltage signal Vᵢₙ+ and negative supply voltage signal Vᵢₙ−) to each power amplifier module 414b₁, . . . , 414b₍ₙ₋₁₎, 414bₙ. In such examples, the power source 514 may be controlled to vary or regulate the positive supply voltage signals Vᵢₙ+ provided to any one or more of power amplifier modules 414b₁, . . . , 414b₍ₙ₋₁₎, 414bₙ.

As shown, power generation system 510 further includes a controller 520 and a power amplifier controller 550 coupled to the power source 514 for controlling the power amplifier modules 414b₁, . . . , 414b₍ₙ₋₁₎, 414bₙ. While power generation system 510 is shown as including standalone controllers 520, 550, it should be appreciated that in other embodiments, the controllers 520, 550 and/or control aspects thereof may be implemented as a common controller. In various embodiments, controller 520 of FIG. 5 may represent a portion or the entirety of bias controller 220b or controller 220′ of FIG. 2.

In FIG. 5, power amplifier controller 550 provides control signals to each power amplifier module 414b₁, . . . , 414b₍ₙ₋₁₎, 414bₙ. For example, controller 550 provides a common clock signal to each power amplifier modules 414b₁, . . . , 414b₍ₙ₋₁₎, 414bₙ to synchronize actuation or deactuation of power amplifier modules 414b₁, . . . , 414b₍ₙ₋₁₎, 414bₙ, as explained above. Additionally, controller 550 provides a specific enable signal to each power amplifier modules 414b₁, . . . , 414b₍ₙ₋₁₎, 414bₙ to actuate or deactuate each power amplifier module 414b₁, . . . , 414b₍ₙ₋₁₎, 414bₙ and to determine the output voltage of each power amplifier modules 414b₁, . . . , 414b₍ₙ₋₁₎, 414bₙ, as explained above.

Controller 520 generally controls the power source 514 and the power amplifier controller 550. For example, wideband sensor 416b may measure or otherwise detect voltage and/or current characteristics of a nonsinusoidal carrier signal generated by one or more power amplifier modules 414b₁, . . . , 414b₍ₙ₋₁₎, 414bₙ. This nonsinusoidal carrier signal is provided to load 432 (of FIG. 4) via matching and filter network 418.

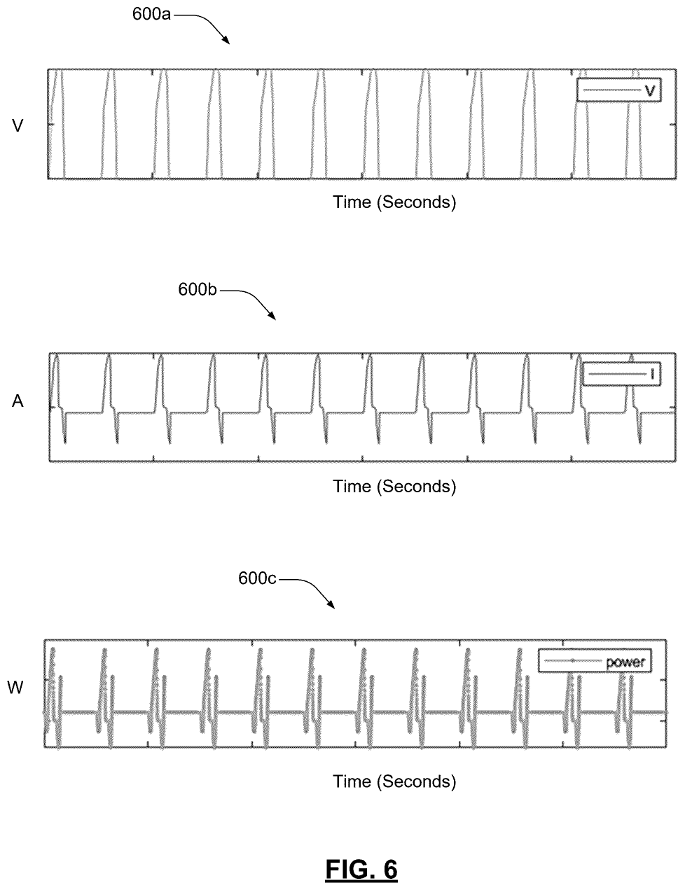

For example, controller 520 receives raw or uncalibrated waveforms associated with the nonsinusoidal carrier signal from wideband sensor 416b. As one nonlimiting example, FIG. 6 shows voltage, current, and instantaneous delivered or active power associated with a bias carrier signal that may be provided to matching and filter network 418 of FIG. 5 via wideband sensor 416b. In FIG. 6, nonsinusoidal waveform 600a represents an uncalibrated output voltage as detected by wideband sensor 416b, nonsinusoidal waveform 600b represents an uncalibrated output current as detected by wideband sensor 416b, and nonsinusoidal waveform 600c represents an instantaneous delivered or active power. In the example of FIG. 6, voltage waveform 600a is generally rectangular with a 400 kHz fundamental frequency. Current waveform 600b is highly asymmetric due to the nonlinear capacitance of load 432 (e.g., a plasma load). Instantaneous delivered or active power shown by waveform 600c may be calculated by, for example, a dot product of waveforms 600a, 600b and/or by using one of frequency domain methods as explained below.

In various embodiments, controller 520 may implement techniques to process the raw or uncalibrated waveforms from wideband sensor 416b in real time. As one example, controller 520 may implement a sample and hold technique to measure received waveforms when the waveforms reach steady state, and then use a scaling factor to obtain calibrated voltage and current values. In such examples, controller 520 can sample into the voltage and current nonsinusoidal waveforms and hold the sampled values at a constant level for a period of time.

In other embodiments, controller 520 may scale and delay the received raw waveforms to approximate voltage and current time domain behaviors. In such examples, controller 520 may multiple and shift the received raw waveforms. In doing so, controller 520 relies on a constant scaling factor to represent a frequency response (e.g., a gain) of wideband sensor 416b. However, the frequency response of wideband sensor 416b is not generally constant (e.g., not flat) and instead changes. As such, the approximate values may be distorted due to the gain of wideband sensor 416b changing across its frequency range.

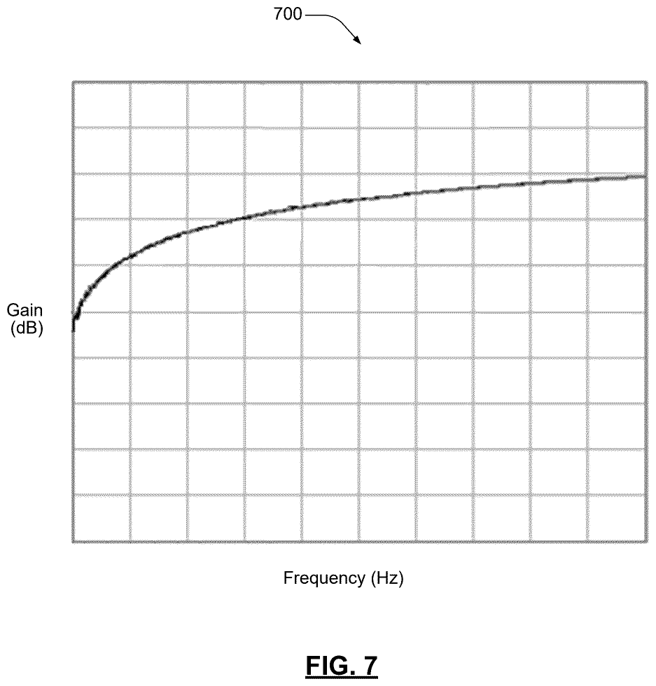

For example, voltage and current sensors, such as sensor 216a, 216b, 416b of FIGS. 2 and 4-5, detect time-varying electric and magnetic fields on an output transmission line coupled to a load (e.g., load 432) via a matching and filter network (e.g., matching and filter network 718), and then attenuate the time-varying fields to correct levels for sampling by controller 520. In such examples, typical sensors have an attenuation factor that varies with frequency. For example, FIG. 7 shows an example frequency response 700 of a wideband sensor, such as wideband sensor 416b. As shown, gain of the wideband sensor (Y-axis) increases as frequency changes (X-axis). As such, to achieve accurate calibration and wideband measurement of the raw waveforms detected by the sensor, controller 520 may compensate for this changing frequency response, as further explained below. In addition, if multiple sensors are employed, the phase or group delay of each sensor may also be frequency-dependent. While measurement of single frequency bias signals can be accomplished with a simple calibration of amplitude and phase, such techniques are much more challenging for wideband signals, such as waveforms 600a, 600b of FIG. 6.

In still other embodiments, controller 520 may implement an equalization filter to process the raw or uncalibrated waveforms from wideband sensor 416b. For example, controller 520 may implement a digital filter or an analog filter to yield constant magnitude and linear phase for the received voltage and current waveforms from wideband sensor 416b. The filter is specifically designed for a particular generator and a particular sensor, such as bias generator 412b and wideband sensor 416b of FIGS. 4-5. In such examples, the filter is placed between sensor 416b and controller 520 to pre-distort received voltage and current waveforms from sensor 416b with an inverse of the frequency response of sensor 416b (e.g., frequency response 700 of FIG. 7).

As another example technique for processing the raw or uncalibrated waveforms from wideband sensor 416b, controller 520 may decompose the nonsinusoidal carrier signal into multiple harmonic components and calibrate the harmonic components individually. Then, controller 520 may perform one or more of many different control options with the calibrated harmonic components, as such reconstructing the wideband signal, compute active and reactive power, compute harmonic load impedances, compute downstream plasma sheath potential, etc. as further explained below.

For example, controller 520 may rely on multiple harmonic components to characterize the received waveforms associated with the nonsinusoidal carrier signal, such as nonsinusoidal waveforms 600a, 600b. In such examples, controller 520 may determine uncalibrated voltage and current values or components at each desired harmonic component of waveforms 600a, 600b. In some examples, a number of harmonic components may be selected depending on, for example, how the characterized voltage and current will be employed. For instance, the number of harmonic components may be ten harmonic components if, for example, the characterized voltage and current is employed for active and reactive power calculations as further explained below. In other examples, the number of harmonic components may be ten or more, such as fifteen harmonic components, twenty harmonic components, etc. Additionally, in various embodiments, the number of harmonic components may vary from one value (e.g., 10) to another value (e.g., 20) over time or be fixed (e.g., remain at 20).

In such examples, wideband sensor 416b may be relied on by controller 520 to look at harmonic components that range up to several MHz. For example, if the nonsinusoidal carrier signal has a fundamental frequency of 400 kHz and the number of harmonic components is twenty, wideband sensor 416b may determine uncalibrated voltage and current values at 400 kHz (fundamental frequency), at a 800 kHz harmonic component (e.g., 400 kHz times 2), at a 1200 kHz harmonic component (e.g., 400 kHz times 3), at a 1600 kHz harmonic component (e.g., 400 kHz times 4), at a 2,000 kHz harmonic component (e.g., 400 kHz times 5), . . . , and at a 8 MHz harmonic component (e.g., 400 kHz times 20).

In various embodiments, controller 520 may sample the uncalibrated waveforms from wideband sensor 416b and determine uncalibrated voltage and current values at the harmonic components of the sampled waveforms. For example, controller 520 may sample waveforms 600a, 600b from wideband sensor 416b at a defined frequency (Fs) and then decompose waveforms 600a, 600b into uncalibrated harmonic voltage and current components. In some examples, the defined frequency (Fs) may be a frequency value greater than the highest carrier harmonic component present in raw waveforms 600a, 600b. As one example, the defined frequency (Fs) may be at least two times greater than the highest harmonic component in waveforms 600a, 600b. For instance, if the nonsinusoidal carrier signal has a fundamental frequency of 400 kHz and the number of harmonic components is twenty, the sampling frequency (Fs) may be 16 MHz (e.g., 2 times 8 MHz at the 20th harmonic component).

In various embodiments, controller 520 may determine the harmonic voltage and current components at each desired harmonic component. For example, controller 520 may implement a Fourier analysis of raw waveforms 600a, 600b (or sampled waveforms 600a, 600b) to obtain complex raw harmonic voltage and current components. Each raw harmonic voltage and current component includes a magnitude value and a phase. For example, if the number of harmonic components is twenty, controller 520 obtains a voltage magnitude and phase and a current magnitude and phase at each of the twenty harmonic components.

Controller 520 may then generate calibrated voltage and current values at each of the harmonic components. For example, each calibrated voltage and current value may be generated based on the corresponding uncalibrated value and a frequency response of wideband sensor 416b. In various embodiments, controller 520 may compensate for the sensor frequency response on each harmonic component based on a chain matrix received or otherwise generated by controller 520. To compensate for the sensor frequency response, controller 520 multiplies the uncalibrated (or raw) voltage and current values by parameters of the chain matrix to obtain complex voltage and current values. These resulting complex voltage and current values represent calibrated, real-time values suitable for downstream processing.

In various examples, the chain matrix may be an ABCD matrix (e.g., a 2×2 matrix) with four parameters determined during calibration of wideband sensor 416b. For example, the parameters of the chain matrix may be determined based on a reference (e.g., a National Institute of Standards and Technology (NIST) traceable reference, etc.). In various embodiments, the A parameter may be voltage, the B parameter may be crosstalk from voltage to current, the C parameter may be crosstalk from current to voltage, and the D parameter may be current. In other embodiments, the parameters may be represented differently if desired.

Once the calibrated voltage and current values are determined, controller 520 may implement various different control options. For example, controller 520 may store the calibrated voltage and current values in memory hardware for later use. Additionally, in some examples, controller 520 may compute active and reactive power, reconstruct the wideband waveforms, compute harmonic load impedances, etc.

For example, controller 520 can determine active power and reactive power associated with the nonsinusoidal waveforms. In such examples, active power represents the power going into a load, such as load 432 (e.g., a plasma chamber), and reactive power represents the power flowing back and forth between, for example, bias generator 412b and load 432. Equations (1)-(5) below demonstrate how active power and/or reactive power are computed. For instance, Equations (1) and (2) represent voltage and current equations, respectively, for calibrated voltage and current values at different harmonic components. In such examples, V in Equation (1) represents a magnitude voltage value at a particular harmonic component and ϕᵥ represents the associated phase angle value at the harmonic component. Similarly, I in Equation (2) represents a magnitude current value at a particular harmonic component and ϕᵢ represents the associated phase angle value at the harmonic component. Equation (3) represents a difference in phase angle (Δϕ) between the voltage phase angle value (ϕᵥ) and the current phase angle value (ϕᵢ). Then, Equations (4) and (5) represent the computations to obtain the active power and the reactive power, respectively, at each harmonic component. To compute the total active power, controller 520 sums all of the determined active power components for each harmonic component (computed with Equation (4)). Likewise, controller 520 sums all of the determined reactive power components for each harmonic component (computed with Equation (5)) to compute the total reactive power.

$$v = V \times cos ( ω t + {ϕ}_{v} ) \qquad ( 1 )$$

$$i = I \times cos ( ω t + {ϕ}_{i} ) \qquad ( 2 )$$

$$Δ ϕ = {ϕ}_{v} - {ϕ}_{i} \qquad ( 3 )$$

$$Active Power = V \times I \times cos ( Δ ϕ ) \qquad ( 4 )$$

$$Reactive Power = V \times I \times sin ( Δ ϕ ) \qquad ( 5 )$$

Then, controller 520 may rely on the computed active power and/or reactive power for controlling bias generator 412b and/or source generator 412a of FIGS. 4-5. For example, in conventional systems, controllers often rely on peak-to-peak voltage for power determination and regulation. In such examples, the controllers may control to a particular voltage and then monitor delivered power and reverse power. However, in some cases, the reliance on voltage may be inaccurate and not repeatable. Using active power and/or reactive power computed based on voltage and current harmonic components calibrated in real time, control of RF generators may be more accurate and repeatable between different systems, different setups, etc. than conventional techniques. Therefore, the use of active power and/or reactive power computed based on real-time, calibrated voltage and current components may provide users with alternate and/or additional control options that are more accurate and repeatable than conventional techniques.

In various embodiments, controller 520 may regulate power provided to load 432 (e.g., to a plasma chamber) based on the determined active power. In such examples, controller 520 may rely on the active power to accelerate ions for etching material (e.g., HAR etching, etc.). Additionally, in some examples, controller 520 may implement protection aspects based on the determined active and/or reactive power. In such examples, controller 520 may implement one or more protection algorithms based on the active and/or reactive power. For example, the reactive power may represent waste heat coming back to bias generator 412b and/or source generator 412a. In such examples, if the active or reactive power exceeds a threshold, controller 520 may generate a warning indicating a fault condition, shut down the power system, etc. for protection purposes.

In some examples, controller 520 may calculate a dissipation associated with the power source 514 based on the active power. For example, controller 520 may compute the active power provided by the power source 514 as explained herein, measure (or otherwise obtain) an input power provided to the power source 514, and then determine a difference between the active power and the input power to obtain a dissipation associated with the power source 514. In such examples, if the dissipation exceeds a threshold, controller 520 may generate a warning indicating a fault condition, shut down the power system, etc. for protection purposes.

Additionally, in various embodiments, controller 520 may reconstruct the wideband waveforms based on the real-time, calibrated voltage and current harmonic components. For example, controller 520 may reconstruct voltage and current waveforms without sensor distortion. For instance, nonsinusoidal waveform 600a, 600b from wideband sensor 416b are often distorted due to, for example, harmonic currents, inductive components, sensor frequency response, etc. However, with the calibrated values, controller 520 can reconstruct nonsinusoidal waveforms representing waveform 600a, 600b without such distortion.

Controller 520 may then use the reconstructed waveforms in different control aspects. For example, controller 520 may use one or both of the reconstructed waveforms to regulate voltage provided by bias generator 412b and/or source generator 412a of FIGS. 4-5. Additionally, in some examples, controller 520 may use one or both of the reconstructed waveforms for shaping the waveform provided by bias generator 412b and/or source generator 412a. In other examples, controller 520 may utilize one or both of the reconstructed waveforms to compute apparent sheath voltage in a plasma chamber.

In various embodiments, controller 520 may also compute harmonic load impedances based on the real-time, calibrated voltage and current harmonic components. In some examples, these computed parameters may be used in system analysis and protection. For example, controller 520 may use the computed harmonic load impedances for arc detection in a plasma chamber or another suitable load. In other examples, controller 520 may use the computed harmonic load impedances for endpoint detection to control (e.g., stop) etching.

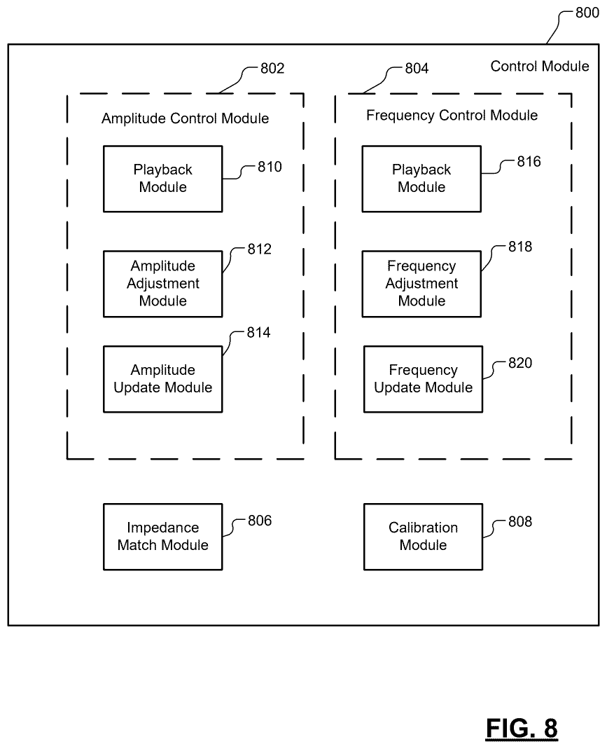

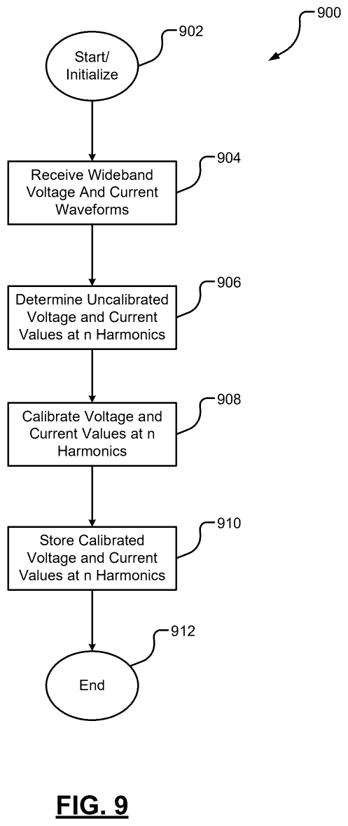

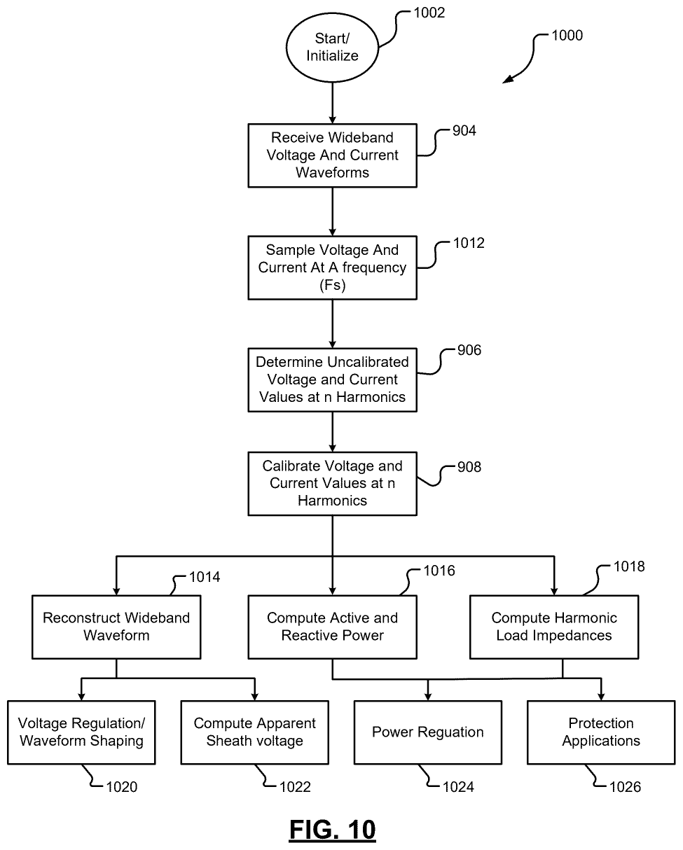

FIG. 8 shows a control module 800. Control module 800 incorporates various components of FIGS. 2 and 4-5. As shown in FIG. 8, control module 800 may include amplitude control module section 802, frequency control module section 804, impedance match module section 806, and calibration module section 808. Amplitude control module section 802 may include one or more of playback module 810, amplitude adjustment module 812, and amplitude update module 814. Frequency control module section 804 may include one or more of playback module 816, frequency adjustment module 818, and frequency update module 820. Impedance match module section 806 may include a frequency control section or a reactive element control section. Calibration module section 808 may include one or more sections for computing uncalibrated voltage and current values at different harmonic components and generating calibrated voltage and current values, as explained herein. In various configurations, control module 800 includes one or a plurality of processors that execute code associated with the module sections or modules 802, 804, 806, 808, 810, 812, 814, 816, 818, 820. Operation of the module sections or modules 802, 804, 806, 808, 810, 812, 814, 816, 818, 820 is described below with respect to the method of FIGS. 9-10.

For further defined structure of controllers 220a, 220b, 220′ of FIG. 2 and controllers 520, 550 of FIG. 5, see the below provided flow chart of FIGS. 9-10 and the below provided definition for the term “module”. The systems disclosed herein may be operated using numerous methods, examples, and various control system methods of which are illustrated in FIGS. 2 and 8. Although the following operations are primarily described with respect to the implementations of FIGS. 2 and 8, the operations may be easily modified to apply to other implementations of the present disclosure. The operations may be iteratively performed. Although the following operations are shown and primarily described as being performed sequentially, one or more of the following operations may be performed while one or more of the other operations are being performed.

FIG. 9 shows a flow chart of a control system 900 for obtaining calibrated measurements of nonsinusoidal signals from sensors in power delivery systems, such as sensors of power delivery systems in FIGS. 2 and 4-5. Control begins at block 902 and proceeds to block 904. At block 904, wideband voltage and current nonsinusoidal waveforms are received from, for example, sensor 416b of FIGS. 4-5, as explained above. Control then proceeds to block 906.

At block 906, uncalibrated voltage and current values are determined at “n” harmonic components of the waveforms. For example, and as explained above, a Fourier analysis or similar analysis may be implemented on received waveforms to obtain raw or uncalibrated voltage and current values at different harmonic components (e.g., ten harmonic components, fifteen harmonic components, twenty harmonic components, etc.). Control then proceeds to block 908.

At block 908, calibrated voltage and current values are generated for the “n” harmonic components. For example, and as explained above, a chain matrix with parameters to compensate for a frequency response of wideband sensor 416b may be used to calibrate the raw voltage and current values for each desired harmonic component. In such examples, uncalibrated voltage and current values may be multiplied by one or more of the parameters to generate the calibrated voltage and current values. Control then proceeds to block 910, where the calibrated voltage and current values at the harmonic components may be stored in memory hardware for later use. Control may then terminate at block 912.

FIG. 10 shows another flow chart of a control system 1000 for obtaining calibrated measurements of nonsinusoidal signals from sensors in power delivery systems, such as sensors of power delivery systems in FIGS. 2 and 4-5. Control begins at block 1002 and proceeds to block 904, where wideband voltage and current nonsinusoidal waveforms are received, as explained above. Control then proceeds to block 1012.

At 1012, the received voltage and current waveforms are sampled at a frequency (Fs). In various embodiments, the voltage and current waveforms may be sampled at a frequency value greater than the highest carrier harmonic component present in the raw waveforms. In some examples, the sampling frequency (Fs) may be at least two times greater than the highest harmonic component, as explained above. Control then proceeds to block 906, 908.

At block 906, uncalibrated voltage and current values are determined at “n” harmonic components of the sampled waveforms, as explained above. Then, at block 908, calibrated voltage and current values are generated for the “n” harmonic components, as explained above. Control then proceeds to any one or more of blocks 1014, 1016, 1018.

At 1014, the wideband waveforms are reconstructed based on the calibrated voltage and current harmonic components generated in block 908. For example, and as explained above, the wideband waveforms may be reconstructed without sensor distortion. Control then proceeds to any one or more of blocks 1020, 1022. At block 1020, the reconstructed voltage and/or current waveforms may be used for voltage regulation and/or waveform shaping, as explained above. At block 1022, the reconstructed voltage and/or current waveforms may be used to compute apparent sheath voltage in a plasma chamber, as explained above.

At 1016, active power and reactive power are computed based on the calibrated voltage and current harmonic components generated in block 908. For example, and as explained above, active power and reactive power may be computed according to Equations (1)-(5) above. Control then proceeds to any one or more of blocks 1024, 1026. At block 1024, the computed active power may be used for power regulation, as explained above. At block 1026, the computed reactive power may be used for one or more protection applications, as explained above.

At 1018, harmonic load impedances are computed based on the calibrated voltage and current harmonic components generated in block 908. Control then proceeds to block 1026, the computed harmonic load impedances may be used for one or more protection applications, as explained above.

The above-described systems and methods may provide one or more of the following benefits. For example, raw or uncalibrated voltage and current sensor signals may be processed in real time to obtain calibrated voltage and current measurements. Such calibrated sensor measurements may be more accurate as compared to other measuring techniques, such as sampling and holding techniques, time-shifting techniques, and filter equalization techniques. Additionally, the calibrated voltage and current measurements enable the creation of additional metrics for feedback and control (e.g., harmonic impedances, active/reactive power, plasma sheath potential estimates, etc.). Further, such calibrated voltage and current measurements and addition metrics for feedback and control are repeatable between different systems, different setups, etc.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. In the written description and claims, one or more steps within a method may be executed in a different order (or concurrently) without altering the principles of the present disclosure. Similarly, one or more instructions stored in a nontransitory computer-readable medium may be executed in a different order (or concurrently) without altering the principles of the present disclosure. Unless indicated otherwise, numbering or other labeling of instructions or method steps is done for convenient reference, not to indicate a fixed order.

Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements.

The phrase “at least one of A, B, and C” should be construed to mean a logical (A OR B OR C), using a nonexclusive logical OR, and should not be construed to mean “at least one of A, at least one of B, and at least one of C.” The term “set” does not necessarily exclude the empty set—in other words, in some circumstances a “set” may have zero elements. The term “nonempty set” may be used to indicate exclusion of the empty set-in other words, a nonempty set will always have one or more elements. The term “subset” does not necessarily require a proper subset. In other words, a “subset” of a first set may be coextensive with (equal to) the first set. Further, the term “subset” does not necessarily exclude the empty set—in some circumstances a “subset” may have zero elements.

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” can be replaced with the term “controller” or the term “circuit.” In this application, the term “controller” can be replaced with the term “module.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); processor hardware (shared, dedicated, or group) that executes code; memory hardware (shared, dedicated, or group) that stores code executed by the processor hardware; other suitable hardware components that provide the described functionality; or a combination of some or all of the above, such as in a system-on-chip.

The module may include one or more interface circuits. In some examples, the interface circuit(s) may implement wired or wireless interfaces that connect to a local area network (LAN) or a wireless personal area network (WPAN). Examples of a LAN are Institute of Electrical and Electronics Engineers (IEEE) Standard 802.11-2020 (also known as the WIFI wireless networking standard) and IEEE Standard 802.3-2018 (also known as the ETHERNET wired networking standard). Examples of a WPAN are IEEE Standard 802.15.4 (including the ZIGBEE standard from the ZigBee Alliance) and, from the Bluetooth Special Interest Group (SIG), the BLUETOOTH wireless networking standard (including Core Specification versions 3.0, 4.0, 4.1, 4.2, 5.0, and 5.1 from the Bluetooth SIG).

The module may communicate with other modules using the interface circuit(s). Although the module may be depicted in the present disclosure as logically communicating directly with other modules, in various implementations the module may actually communicate via a communications system. The communications system includes physical and/or virtual networking equipment such as hubs, switches, routers, and gateways. In some implementations, the communications system connects to or traverses a wide area network (WAN) such as the Internet. For example, the communications system may include multiple LANs connected to each other over the Internet or point-to-point leased lines using technologies including Multiprotocol Label Switching (MPLS) and virtual private networks (VPNs).

In various implementations, the functionality of the module may be distributed among multiple modules that are connected via the communications system. For example, multiple modules may implement the same functionality distributed by a load balancing system. In a further example, the functionality of the module may be split between a server (also known as remote, or cloud) module and a client (or, user) module. For example, the client module may include a native or web application executing on a client device and in network communication with the server module.

Some or all hardware features of a module may be defined using a language for hardware description, such as IEEE Standard 1364-2005 (commonly called “Verilog”) and IEEE Standard 1076-2008 (commonly called “VHDL”). The hardware description language may be used to manufacture and/or program a hardware circuit. In some implementations, some or all features of a module may be defined by a language, such as IEEE 1666-2005 (commonly called “SystemC”), that encompasses both code, as described below, and hardware description.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

The memory hardware may also store data together with or separate from the code. Shared memory hardware encompasses a single memory device that stores some or all code from multiple modules. One example of shared memory hardware may be level 1 cache on or near a microprocessor die, which may store code from multiple modules. Another example of shared memory hardware may be persistent storage, such as a solid state drive (SSD), which may store code from multiple modules. Group memory hardware encompasses a memory device that, in combination with other memory devices, stores some or all code from one or more modules. One example of group memory hardware is a storage area network (SAN), which may store code of a particular module across multiple physical devices. Another example of group memory hardware is random access memory of each of a set of servers that, in combination, store code of a particular module.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and nontransitory. Nonlimiting examples of a nontransitory computer-readable medium are nonvolatile memory devices (such as a flash memory device, an erasable programmable read-only memory device, or a mask read-only memory device), volatile memory devices (such as a static random access memory device or a dynamic random access memory device), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. Such apparatuses and methods may be described as computerized apparatuses and computerized methods. The functional blocks and flowchart elements described above serve as software specifications, which can be translated into the computer programs by the routine work of a skilled technician or programmer.

The computer programs include processor-executable instructions that are stored on at least one nontransitory computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A power supply system comprising:
a RF generator configured to output a nonsinusoidal signal to a load;
at least one wideband sensor configured to measure at least one of a voltage and a current of the nonsinusoidal signal; and
a controller coupled to the RF generator, the controller configured to receive a waveform associated with the nonsinusoidal signal from the at least one wideband sensor, determine an uncalibrated value at each of a number of harmonic components of the waveform, and generate a calibrated value at each of the number of harmonic components based on the corresponding uncalibrated value and a frequency response of the at least one wideband sensor.

2. The power supply system of claim 1, wherein:
the waveform is a voltage waveform;
the calibrated value at each of the number of harmonic components is a calibrated voltage value; and
the controller is configured to receive a current waveform associated with the nonsinusoidal signal from the at least one wideband sensor, determine an uncalibrated current value at each of a number of harmonic components of the current waveform, and generate a calibrated current value at each of the number of harmonic components based on the corresponding uncalibrated value and a frequency response of the at least one wideband sensor.

3. The power supply system of claim 1, wherein the controller configured to:
sample the waveform at a defined frequency; and
determine the uncalibrated value at each of the number of harmonic components of the sampled waveform.

4. The power supply system of claim 1, wherein the number of harmonic components is twenty harmonic components.

5. The power supply system of claim 1, wherein the controller is configured to determine the uncalibrated value at each of the number of harmonic components of the waveform based on a Fourier analysis of the waveform.

6. The power supply system of claim 1, wherein:
the calibrated value at each of the number of harmonic components includes a voltage or current magnitude and an associated phase; and
the controller is configured to receive a chain matrix including parameters, and multiply the voltage or current magnitude at each of the number of harmonic components by one of the parameters of the chain matrix and the associated phase by another one of the parameters of the chain matrix to generate the calibrated value.

7. The power supply system of claim 1, wherein the controller is configured to determine at least one of active power and reactive power associated with the nonsinusoidal signal.

8. The power supply system of claim 7, wherein the controller is configured to control the RF generator based on the at least one of the active power and the reactive power.

9. The power supply system of claim 7, wherein the controller is configured to generate a warning based on the at least one of the active power and the reactive power.

10. The power supply system of claim 1, wherein:
the nonsinusoidal signal is a carrier signal;
the RF generator is controlled to pulse the carrier signal;
the nonsinusoidal carrier signal is at least one of a rectangular or piecewise linear waveform; and
wherein the pulse is one of a rectangular, trapezoidal, triangular, sawtooth, or gaussian pulse waveform.

11. The power generator of claim 10 wherein the pulse includes a plurality of states.

12. A nontransitory computer-readable medium storing processor-executable instructions, the instructions comprising:
receiving, from at least one wideband sensor, a waveform associated with a nonsinusoidal signal;
determining an uncalibrated value at each of a number of harmonic components of the waveform; and
generating a calibrated value at each of the number of harmonic components based on the corresponding uncalibrated value and a frequency response of the at least one wideband sensor.

13. The nontransitory computer-readable medium storing processor-executable instructions of claim 12, further comprising storing the calibrated value at each of the number of harmonic components.

14. The nontransitory computer-readable medium storing processor-executable instructions of claim 12, wherein:
the instructions further comprise sampling the waveform at a defined frequency; and
determining the uncalibrated value at each of the number of harmonic components of the waveform includes determining the uncalibrated value at each of the number of harmonic components of the sampled waveform.

15. The nontransitory computer-readable medium storing processor-executable instructions of claim 12, wherein:
the instructions further comprise receiving a chain matrix including parameters; and
generating the calibrated value at each of the number of harmonic components includes multiplying components of the uncalibrated value at each of the number of harmonic components by the parameters of the chain matrix to generate the calibrated value.

16. The nontransitory computer-readable medium storing processor-executable instructions of claim 12, further comprising:
determining at least one of active power and reactive power associated with the nonsinusoidal signal; and
controlling an RF generator to output a signal to a load based on the at least one of the active power and the reactive power.

17. A controller for a RF generator configured to output a nonsinusoidal signal to a load, the controller comprising:
a power controller configured to receive, from at least one wideband sensor, a waveform associated with a nonsinusoidal signal, determine an uncalibrated value at each of a number of harmonic components of the waveform, and generate a calibrated value at each of the number of harmonic components based on the corresponding uncalibrated value and a frequency response of the at least one wideband sensor.

18. The controller of claim 17, wherein the power controller is configured to store the calibrated value at each of the number of harmonic components.

19. The controller of claim 17, wherein the power controller is configured to:
sample the waveform at a defined frequency; and
determine the uncalibrated value at each of the number of harmonic components of the sampled waveform.

20. The controller of claim 17, wherein the number of harmonic components is ten or more harmonic components.

21. The controller of claim 17, wherein the power controller is configured to:
receive a chain matrix including parameters; and
multiply components of the uncalibrated value at each of the number of harmonic components by the parameters of the chain matrix to generate the calibrated value.

22. The controller of claim 17, wherein the power controller is configured to:
determine at least one of active power and reactive power associated with the nonsinusoidal signal; and
control an RF generator to output a signal to a load based on the at least one of the active power and the reactive power.
